(19) United States
(12) Patent Application Publication
(10) Pub. No.: US 2023/0209813 A1
(43) Pub. Date: Jun. 29, 2023

(54) METHOD OF FABRICATING A SEMICONDUCTOR DEVICE INCLUDING CONTACT PLUG AND SEMICONDUCTOR DEVICE

(71) Applicant: SAMSUNG ELECTRONICS CO., LTD., SUWON-SI (KR)

(72) Inventors: Yuna LEE, Hwaseong-si (KR); Sangwuk PARK, Hwaseong-si (KR); Hyunchul YOON, Seongnam-si (KR); Minji LEE, Suwon-si (KR); Jungpyo HONG, Gwangmyrong-di (KR)

(21) Appl. No.: 17/961,688

(22) Filed: Oct. 7, 2022

(30) Foreign Application Priority Data
Dec. 28, 2021 (KR) 10-2021-0189555

(51) Int. Cl. H01L 27/108; H01L 23/528; H01L 23/522

(52) U.S. Cl. CPC H01L 27/10888; H01L 27/10885; H01L 23/5283; H01L 23/5226; H01L 27/10823; H01L 27/10897; H01L 27/10876; H01L 27/10894

(57) ABSTRACT

A method of fabricating a semiconductor device includes forming interconnection structures on a lower structure. An insulating layer is formed between the interconnection structures. The insulating layer is patterned to form insulating patterns. An insulating fence is formed between the insulating patterns. A first protective pattern is formed on the insulating fence. The insulating patterns are etched after the forming of the first protective pattern to form contact holes. Contact plugs are formed in the contact holes.

### CROSS-REFERENCE TO RELATED APPLICATION(S)

This application claims priority under 35 U.S.C. § 119 to Korean Patent Application No. 10-2021-0189555, filed on Dec. 28, 2021 in the Korean Intellectual Property Office, the disclosure of which is incorporated by reference in its entirety herein.

### 1. TECHNICAL FIELD

The present inventive concept relates to a method of fabricating a semiconductor device including a contact plug, and to a semiconductor device fabricated using the method.

### 2. DISCUSSION OF RELATED ART

Research is being conducted concerning reducing sizes of components constituting a semiconductor device and increasing performance thereof. For example, in a DRAM, research is being conducted for reliably and stably forming elements with reduced sizes.

### SUMMARY

An aspect of the present inventive concept is to provide a method of fabricating a semiconductor device including a contact plug.

Another aspect of the present inventive concept is to provide a semiconductor device fabricated using the method.

According to an embodiment of the present inventive concept, a method of fabricating a semiconductor device includes forming interconnection structures on a lower structure. An insulating layer is formed between the interconnection structures. The insulating layer is patterned to form insulating patterns. An insulating fence is formed between the insulating patterns. A first protective pattern is formed on the insulating fence. The insulating patterns are etched after the forming of the first protective pattern to form contact holes. Contact plugs are formed in the contact holes.

According to an embodiment of the present inventive concept, a method of fabricating a semiconductor device includes forming a lower structure including first regions and second regions. Interconnection structures are formed on the lower structure. The interconnection structures are electrically connected to the first regions. Patterns are formed between the interconnection structures. An insulating fence is formed between the patterns. A forming a first protective pattern on the insulating fence and second protective patterns on the interconnection structures are simultaneously formed. The patterns are etched after the forming of the first and second protective patterns to form contact holes. Contact plugs are formed in the contact holes. The contact plugs are electrically connected to the second regions.

According to an embodiment of the present inventive concept, a method of fabricating a semiconductor device includes forming an isolation layer defining active regions on a substrate. Cell transistors are formed that include gate structures, and first and second impurity regions. The gate structures cross the active regions and extend into the isolation layer. The first and second impurity regions are formed in the active regions. Bit line structures are formed that are disposed on the cell transistors, the active regions, and the isolation layer. The bit line structures extend parallel to each other. insulating patterns are formed between the bit line structures. An insulating fence is formed between the insulating patterns. A first protective pattern on the insulating fence and second protective patterns on the bit line structures are simultaneously formed. The insulating patterns are etched after the forming of the first and second protective patterns to form contact holes. Contact plugs are formed in the contact holes.

According to an embodiment of the present inventive concept, a semiconductor device includes an isolation layer defining active regions on a substrate. Cell transistors include gate structures crossing the active regions and extending into the isolation layer, and first and second impurity regions in the active regions. Bit line structures are disposed on the cell transistors, the active regions, and the isolation layer. The bit line structures extend parallel to each other. Insulating fences are between the bit line structures. First protective patterns are on the insulating fences. Second protective patterns are on the bit line structures. A contact plug is disposed between the bit line structures and between the insulating fences. A portion of the contact plug is positioned at a same level as the first and second protective patterns.

### BRIEF DESCRIPTION OF DRAWINGS

The above and other aspects, features, and advantages of embodiments of the present inventive concept will be more clearly understood from the following detailed description, taken in conjunction with the accompanying drawings, in which:

FIG. 1 is a process flow diagram schematically illustrating a method of fabricating a semiconductor device according to an embodiment of the present inventive concept.

FIG. 2 is a plan view schematically illustrating a semiconductor device according to an embodiment of the present inventive concept.

FIGS. 3A to 3K are cross-sectional views schematically illustrating a method of fabricating a semiconductor device according to embodiments of the present inventive concept.

FIGS. 4A and 4B are cross-sectional views schematically illustrating a method of fabricating a semiconductor device according to embodiments of the present inventive concept.

FIGS. 5A and 5B are cross-sectional views schematically illustrating a method of fabricating a semiconductor device according to embodiments of the present inventive concept.

FIGS. 6A and 6B are cross-sectional views schematically illustrating a method of fabricating a semiconductor device according to embodiments of the present inventive concept.

FIG. 7 is a cross-sectional view schematically illustrating a method of fabricating a semiconductor device according to an embodiment of the present inventive concept.

FIG. 8 is a cross-sectional view schematically illustrating a method of fabricating a semiconductor device according to an embodiment of the present inventive concept.

FIGS. 9A and 9B are cross-sectional views schematically illustrating a method of fabricating a semiconductor device according to embodiments of the present inventive concept.

FIGS. 10A and 10B are cross-sectional views schematically illustrating a method of fabricating a semiconductor device according to embodiments of the present inventive concept.

### DETAILED DESCRIPTION OF EMBODIMENTS

Hereinafter, terms such as “upper,” “intermediate,” and “lower” may also be used to be replaced with other terms, for example, “first,” “second,” and “third,” to describe the elements of the specification. Terms such as “first,” “second,” and “third” may be used to describe various components, but the components are not necessarily limited by the terms. A “first component” may be called a “second component,” or may be named as another term, distinguishable from other components.

Hereinafter, a method of fabricating a semiconductor device and the semiconductor device fabricated using the method, according to embodiments of the present inventive concept, will be described.

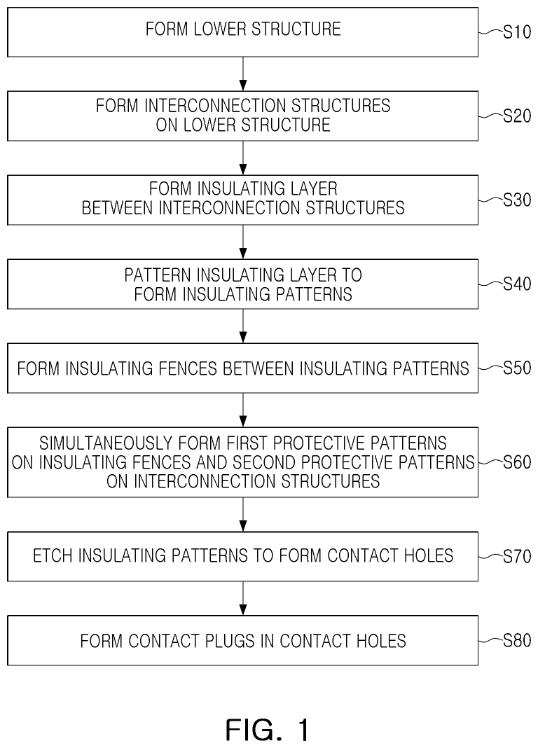

First, referring to FIGS. 1, 2, and 3A to 3K, a method of fabricating a semiconductor device and the semiconductor device fabricated using the method, according to embodiments of the present inventive concept, will be described.

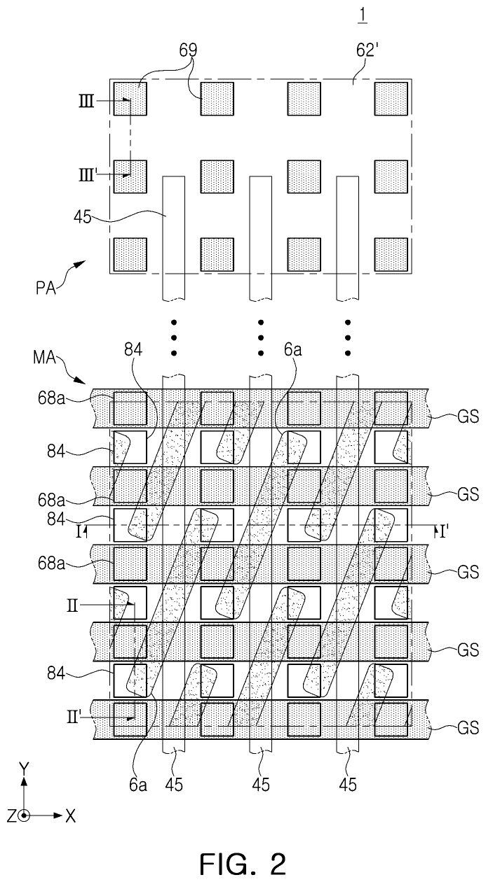

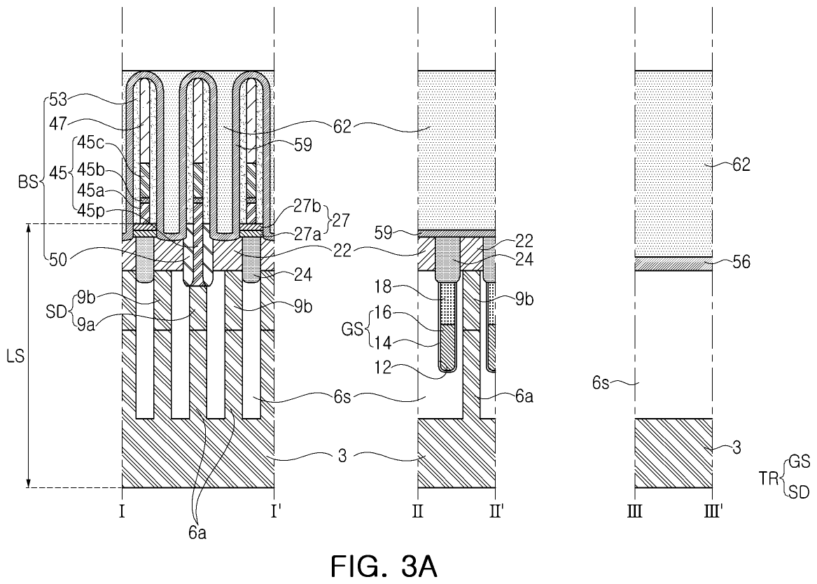

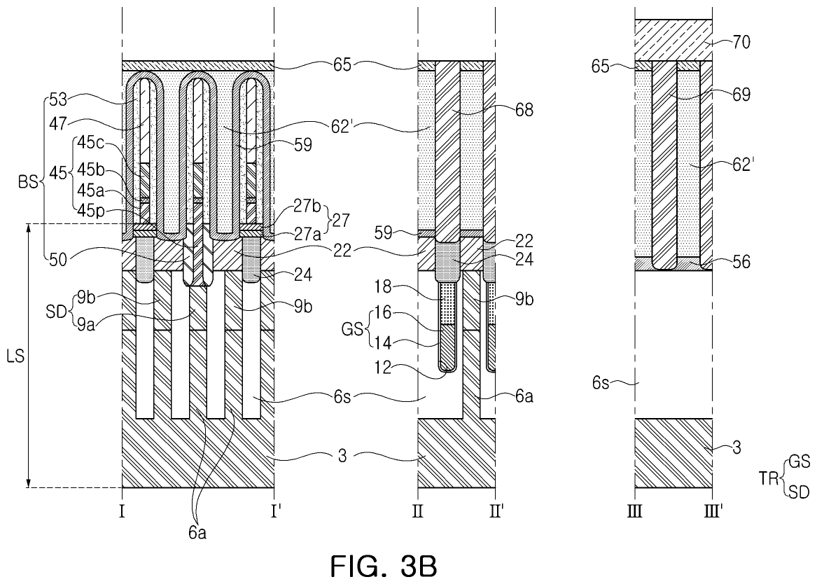

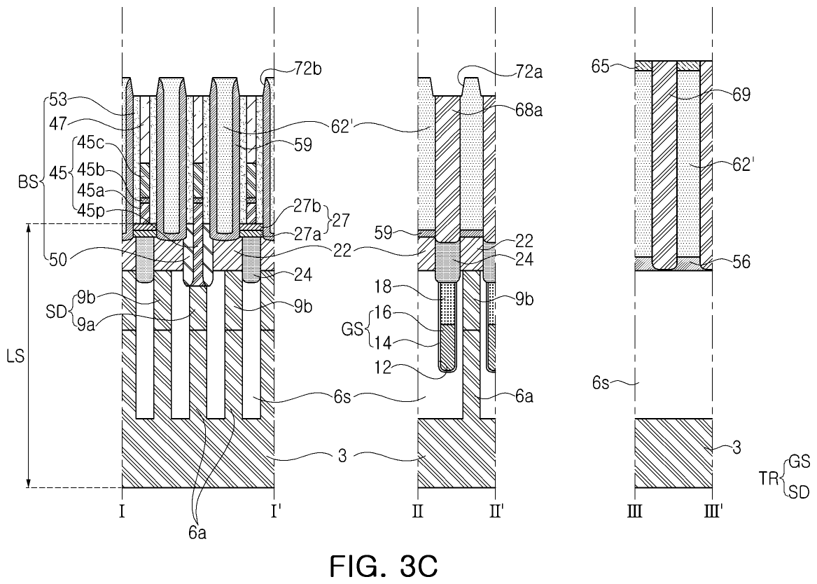

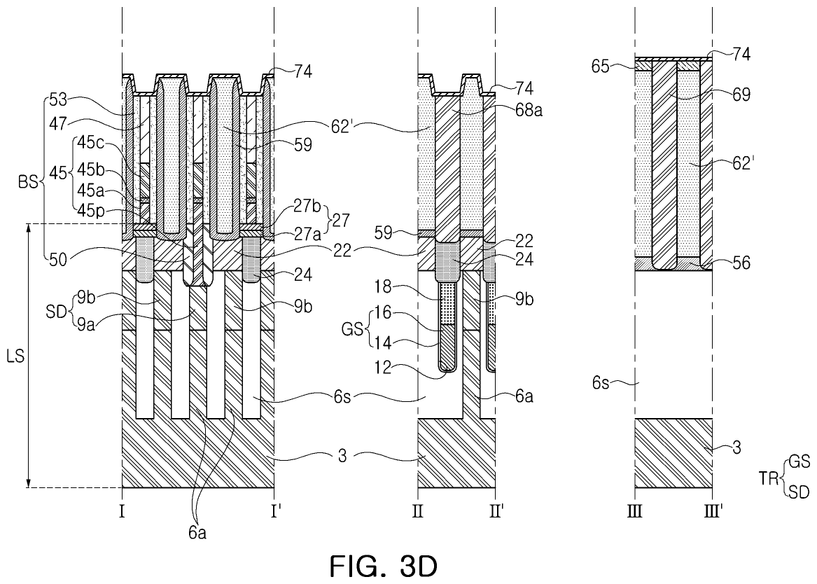

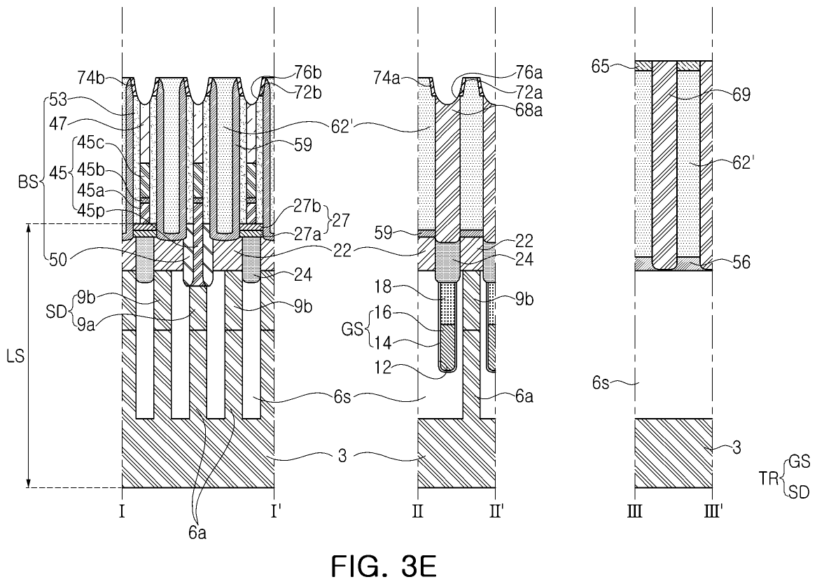

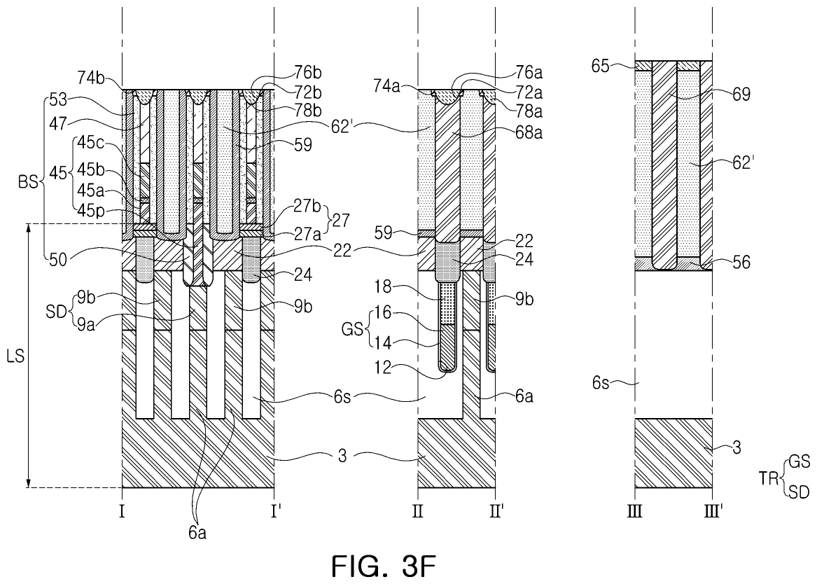

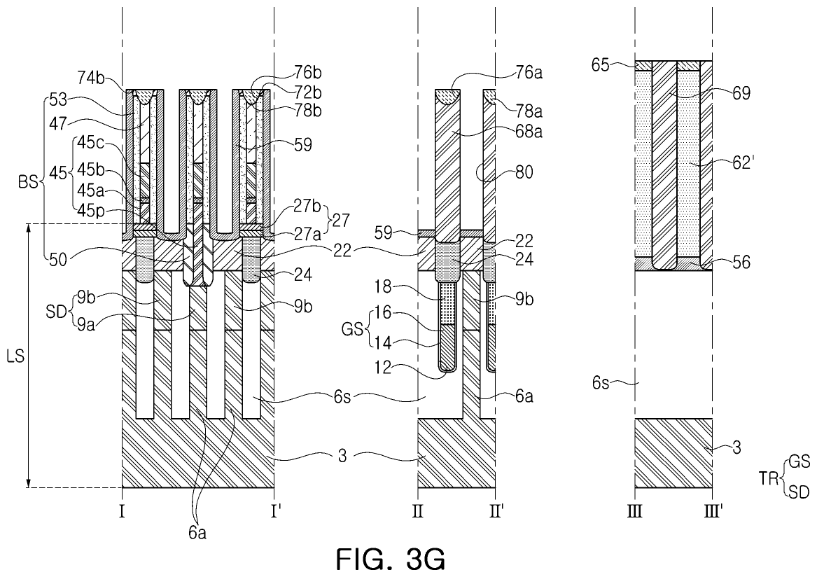

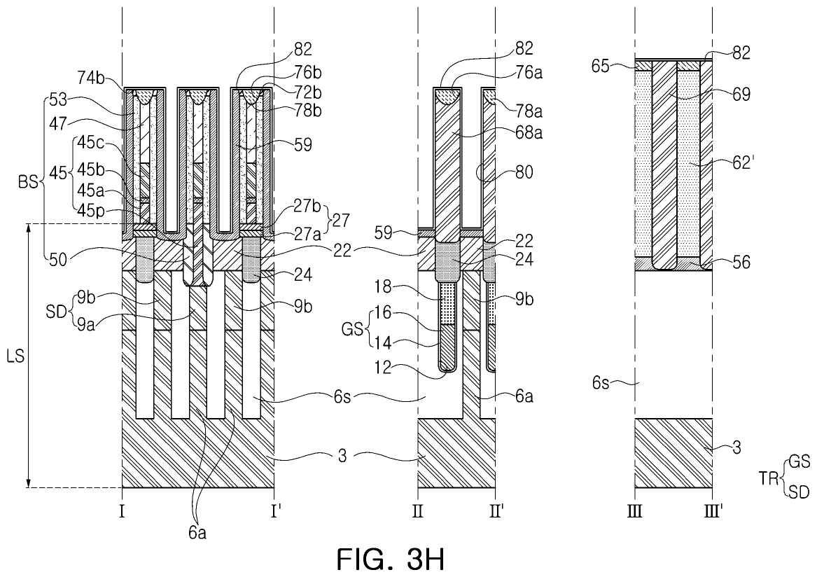

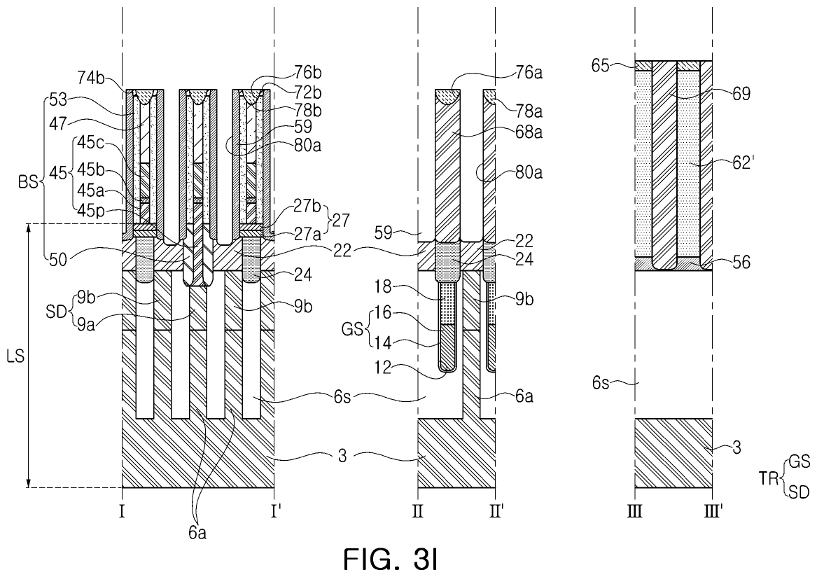

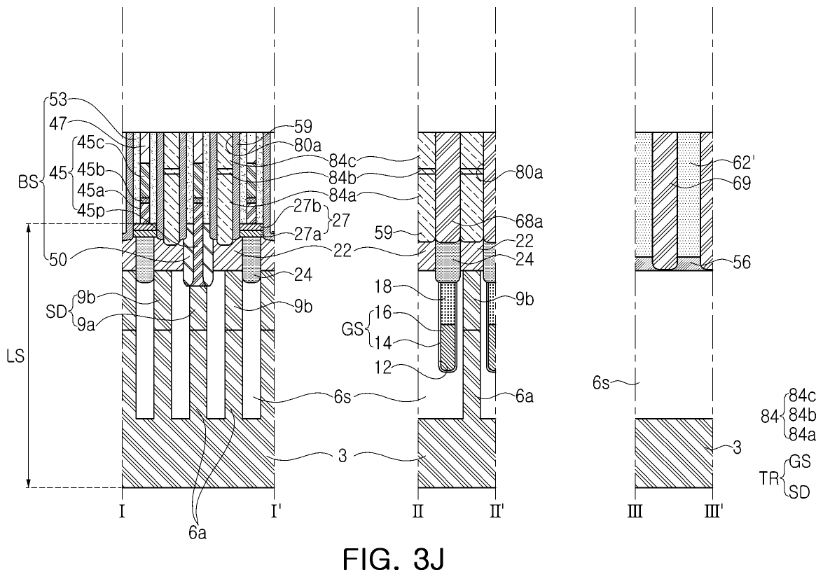

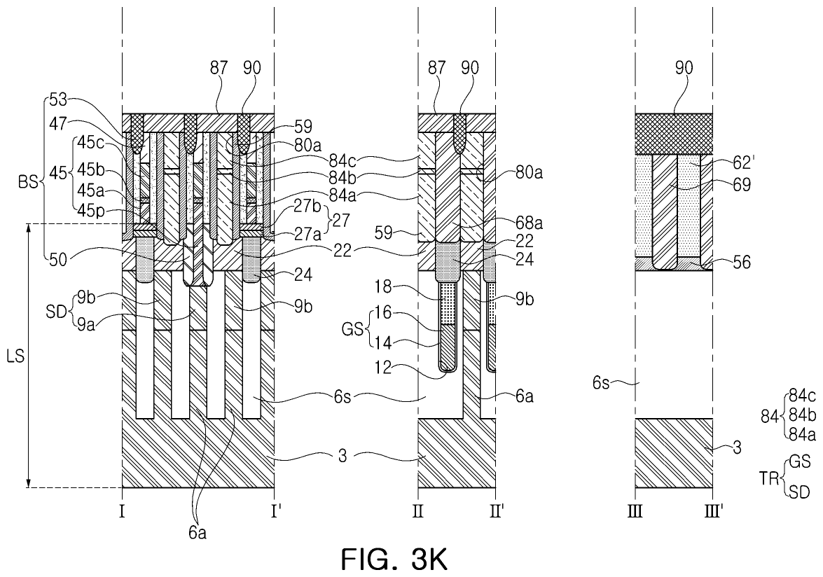

In FIGS. 1, 2, and 3A to 3K, FIG. 1 is a process flow diagram schematically illustrating a method of fabricating a semiconductor device according to embodiments of the present inventive concept, FIG. 2 is a plan view schematically illustrating a semiconductor device according to an embodiment of the present inventive concept, and FIGS. 3A to 3K are cross-sectional views schematically illustrating an example of a method of fabricating a semiconductor device according to embodiments of the present inventive concept. FIGS. 3A to 3K may be cross-sectional views illustrating regions taken along line I-I′, line II-II′, and line III-III′ of FIG. 2. In this case, FIG. 3K may be a cross-sectional view schematically illustrating a semiconductor device according to an embodiment of the present inventive concept.

Referring to FIGS. 1, 2, and 3A, a lower structure LS may be formed in block S10. Forming the lower structure LS may include forming cell transistors TR.

The cell transistors TR may be formed on a substrate 3. In an embodiment, the substrate 3 may be a semiconductor substrate. For example, the substrate 3 may be formed of a semiconductor material such as silicon or the like.

The forming of the cell transistors TR may include forming a device isolation layer 6s defining active regions 6a on the substrate 3, forming gate trenches 12 crossing the active regions 6a and extending into the device isolation layer 6s, and forming cell gate structures GS respectively filling the gate trenches 12.

Each of the cell gate structures GS may include a gate dielectric layer 14 conformally covering an inner wall of each of the gate trenches 12, and a gate electrode 16 partially filling each of the gate trenches 12 on the gate dielectric layer 14.

The forming of the lower structure LS may further include forming a gate capping layer 18 filling a remaining portion of each of the gate trenches 12 on the gate electrode 16.

In an embodiment, the gate electrode 16 may include doped polysilicon, metal, conductive a metal nitride, a metal-semiconductor compound, conductive a metal oxide, graphene, carbon nanotube, or a combination thereof. For example, the gate electrode 16 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, or a combination thereof. However, embodiments of the present inventive concept are not necessarily limited thereto. The gate electrode 16 may include a single layer or multiple layers of the materials described above. For example, the gate electrode 16 may include a first electrode layer that may be formed of a metal material, and a second electrode layer that may be formed of doped polysilicon on the first electrode layer. The gate capping layer 18 may include an insulating material, for example, silicon nitride.

The forming of the cell transistors TR may further include forming source/drain regions SD in the active regions 6a in an ion implantation process. The source/drain regions SD may include first and second impurity regions 9a and 9b spaced apart from each other. The first and second impurity regions 9a and 9b may be formed in the active regions 6a.

In an embodiment, the source/drain regions SD may be formed before the device isolation layer 6s is formed.

In an embodiment, the source/drain regions SD may be formed after the device isolation layer 6s is formed, and before the gate trenches 12 are formed.

In an embodiment, the source/drain regions SD may be formed after the gate structures GS and the gate capping layer 18 are formed.

In an embodiment, the active regions 6a may be formed of single crystal silicon. The active regions 6a may have P-type conductivity, and the first and second impurity regions 9a and 9b may have N-type conductivity. However, embodiments of the present inventive concept are not necessarily limited thereto.

The forming of the lower structure LS may further include forming pad layers 22 on the cell transistors TR and the device isolation layer 6s, and an insulating fence layer 24 separating the pad layers 22. The pad layers 22 may be electrically connected to and in direct contact with the second impurity regions 9b among the first and second impurity regions 9a and 9b of the source/drain regions S/D. For example, an upper portion of the second impurity regions 9b may directly contact a lower portion of the pad layers 22.

In an embodiment, the pad layers 22 may be formed as a doped silicon layer, for example, a polysilicon layer having N-type conductivity. The insulating fence layer 24 may be formed of an insulating material such as silicon nitride or the like.

The forming of the lower structure LS may further include forming a buffer layer 27. The buffer layer 27 may include at least one material layer. For example, the buffer layer 27 may include a first buffer layer 27a and a second buffer layer 27b on the first buffer layer 27a. In an embodiment, the first buffer layer 27a and the second buffer layer 27b may be formed of different insulating materials. For example, the first buffer layer 27a may be formed of silicon oxide, and the second buffer layer 27b may be formed of silicon nitride. However, embodiments of the present inventive concept are not necessarily limited thereto.

In an embodiment in which the semiconductor device 1 is a memory device, for example, a DRAM device, the lower structure LS may be formed in a memory cell region MA and a peripheral region PA around the memory cell region MA.

The cell transistors TR may be disposed in the memory cell region MA.

Interconnection structures BS may be formed on the lower structure LS in block S20. The forming each of the interconnection structures BS in turn may include forming a conductive line 45 and an interconnection capping layer 47, stacked in sequence, and forming insulating spacers on a lateral side surface of the conductive line 45 and a lateral side surface of the interconnection capping layer 47.

In each of the interconnection structures BS, the conductive line 45 may include a first layer 45a, a second layer 45b, and a third layer 45c sequentially stacked, and a portion of the first layer 45a may extend in a downward direction, to form a plug portion 45p electrically connected to the first impurity region 9a among the source/drain regions SD.

In an embodiment, the first layer 45a may be formed as a doped silicon layer, the second layer 45b may be formed as a metal-semiconductor compound layer (e.g., WN, TiN, or the like), and the third layer 45c may be formed as a metal layer (e.g., W or the like).

In an embodiment, the interconnection structures BS may be bit line structures. For example, the conductive line 45 may be a bit line including the plug portion 45p electrically connected to the first impurity region 9a. In an embodiment, the conductive line 45 may be a bit line of a memory device such as DRAM or the like.

The insulating spacers may include lower spacers 50 covering lateral side surfaces of the plug portion 45p of the first layer 45a, and sidewall spacers 53 covering lateral side surfaces of the conductive line 45 on a higher level of the buffer layer 27.

In an embodiment, the insulating spacers, such as the lower spacer 50 and the sidewall spacer 53 may include at least one of insulating materials such as silicon oxide, silicon oxynitride, silicon nitride, or the like. However, embodiments of the present inventive concept are not necessarily limited thereto.

In an embodiment, while forming the interconnection structures BS, the buffer layer 27 that does not overlap the interconnection structures BS may be etched. Therefore, in the memory cell region MA, the buffer layer 27 may remain in the interconnection structures BS.

The interconnection structures BS may cross the memory cell region MA, and may extend into the peripheral region PA.

In the plan view, the gate structure GS may extend in a first direction (X), and the interconnection structures BS may extend in a second direction (Y), perpendicular to the first direction (X).

An insulating liner 59 may be formed to cover upper surfaces and lateral side surfaces of the interconnection structures BS and to cover a bottom surface between the interconnection structures BS. In an embodiment, the insulating liner 59 may include an insulating material such as silicon nitride or the like.

In some embodiments, a protective insulating layer 56 may be formed on the device isolation layer 6s in the peripheral region PA. In an embodiment, the protective insulating layer 56 may include an insulating material such as silicon oxide, silicon nitride, or the like.

In an embodiment, at least a portion of the protective insulating layer 56 may be formed on the device isolation layer 6s in the peripheral region PA, before forming the pad layers 22.

In an embodiment, the protective insulating layer 56 may be formed of a first material layer formed on the device isolation layer 6s in the peripheral region PA, and a second material layer of the insulating liner 59, before forming the pad layers 22. In an embodiment, the first and second material layers may include silicon nitride.

An insulating layer 62 may be formed between the interconnection structures BS in block S30. The insulating layer 62 may be formed on the insulating liner 59 and the protective insulating layer 56. Therefore, the insulating layer 62 may be formed between the interconnection structures BS, and may be formed on the protective insulating layer 56. In an embodiment, the insulating layer 62 may be formed of an insulating material such as silicon oxide or the like.

Referring to FIGS. 1, 2, and 3B, the insulating layer 62 may be patterned to form insulating patterns 62′ in block S40. The forming of the insulating patterns 62′ may include forming an upper capping layer 65 on the insulating layer 62, and patterning the upper capping layer 65 and the insulating layer 62. The upper capping layer 65 may be formed to have a linear shape extending in the first direction (X).

In the memory cell region MA, the insulating patterns 62′ may be formed on the pad layers 22.

Insulating fences 68 may be formed between the insulating patterns 62′ in block S50. For example, each of the insulating fences 68 may be formed between adjacent insulating patterns 62′ of the insulating patterns 62′ (e.g., in a horizontal direction). Upper surfaces of the insulating fences 68 may be coplanar with an upper surface of the upper capping layer 65. The insulating fences 68 may be formed in the memory cell region MA.

In an embodiment, dummy barriers 69 may be formed between the insulating patterns 62′ in the peripheral region PA. The dummy barriers 69 may be formed simultaneously with the insulating fences 68, and may be formed of the same material as the insulating fences 68.

In an embodiment, the insulating patterns 62′ and the insulating fences 68 may be formed of different materials. For example, the insulating patterns 62′ may be formed of silicon oxide, and the insulating fences 68 may be formed of silicon nitride. However, embodiments of the present inventive concept are not necessarily limited thereto.

A mask layer 70 may be formed on the dummy barriers 69 and the upper capping layer 65 in the peripheral region PA. The mask layer 70 may be formed in the peripheral region PA, and may expose the insulating fences 68 and the upper capping layer 65 in the memory cell region MA.

In an embodiment, the insulating patterns 62′ in the memory cell region MA may not be formed of an insulating material. Therefore, the insulating patterns 62′ may be referred to as sacrificial patterns or patterns.

Referring to FIGS. 1, 2, and 3C, an etching process using the mask layer (70 in FIG. 3B) as an etching mask may be performed to etch the upper capping layer 65, and to then partially etch the insulating fences 68 and the interconnection structures BS. Therefore, first upper recess regions 72a may be formed on insulating fences 68a, partially etched, and second upper recess regions 72b may be formed on the partially etched interconnection structures BS.

In the memory cell region MA, upper surfaces of the insulating fences 68a may be disposed on a level lower than upper surfaces of the insulating patterns 62′.

The mask layer (70 in FIG. 3B) may be removed.

In an embodiment, a width of each of the first upper recess regions 72a may be wider than a width of each of the insulating patterns 62′.

Referring to FIGS. 1, 2, and 3D, an upper protective layer 74 may be formed on inner walls of the first and second upper recess regions 72a and 72b.

In an embodiment, the upper protective layer 74 may be formed of an insulating material. For example, the upper protective layer 74 may be formed of silicon oxide. For example, the upper protective layer 74 may be formed of silicon oxide by an atomic layer deposition process. However, embodiments of the present inventive concept are not necessarily limited thereto. For example, in an embodiment, the upper protective layer 74 may be formed of an insulating material or a conductive material, different from silicon oxide. For example, the upper protective layer 74 may include silicon nitride, a metal oxide, or a metal nitride.

Referring to FIGS. 1, 2, and 3E, the insulating fences 68 below the first upper recess regions 72a and the interconnection structure BS below the second upper recess regions 72b may be partially etched while etching the upper protective layer 74. The upper protective layer 74 may be formed as a first upper protective layer 74a remaining on lateral side surfaces of the first upper recess regions 72a, and as a second upper protective layer 74b remaining on lateral side surfaces of the second upper recess regions 72b. The first and second upper protective layers 74a, 74b may expose lower surfaces of the first and second upper recess regions 72a, 72b, respectively.

The insulating fences 68 below the first upper recess regions 72a may be partially etched to form first lower recess regions 76a below the first upper recess regions 72a, and the interconnection structure BS below the second upper recess regions 72b may be partially etched to form second lower recess regions 76b below the second upper recess regions 72b.

Referring to FIGS. 1, 2, and 3F, a core protective layer may be formed on the substrate 3 after performing the operations including the forming of the first and second lower recess regions 76a and 76b, and the core protective layer may be planarized. The planarization may include etching the core protective layer. The core protective layer may include first core protective layers 78a filling the first upper recess regions 72a and the first lower recess regions 76a, and a second core protective layer 78b filling the second upper recess regions 72b and the second lower recess regions 76b.

The first and second core protective layers 78a and 78b may be formed of a material having etching selectivity for a material of the insulating patterns 62′.

In an embodiment, the first and second core protective layers 78a and 78b may be formed of a material having high etching selectivity for a material of the insulating patterns 62′, for example, a conductive material. For example, the first and second core protective layers 78a and 78b may be formed of a metal nitride such as TiN or the like. However, embodiments of the present inventive concept are not necessarily limited thereto and the materials of the first and second core protective layers 78a and 78b may be replaced with other materials having high etching selectivity for a material of the insulating patterns 62′. For example, in an embodiment the first and second core protective layers 78a and 78b may be formed of an insulating material such as a metal oxide, silicon nitride, or the like. Each of the first and second core protective layers 78a and 78b may be formed as a single layer or in multiple layers.

The first upper protective layers 74a and the first core protective layers 78a may constitute first protective patterns 74a and 78a, and the second upper protective layers 74b and the second core protective layers 78b may constitute second protective patterns 74b and 78b.

Therefore, the first protective patterns 74a and 78a on the insulating fences 68a and the second protective patterns 74b and 78b on the interconnection structures BS may be simultaneously formed in block S60.

Referring to FIGS. 1, 2 and 3G, the insulating patterns 62′ may be etched to form contact holes 80 in block S70.

The forming of the contact holes 80 may include selectively etching and removing the insulating patterns 62′ in the memory cell region MA. While the insulating patterns 62′ are selectively etched and removed in the memory cell region MA, the first protective patterns 74a and 78a and the second protective patterns 74b and 78b may protect the insulating fences 68a and the interconnection structures BS. For example, the first core protective layers 78a may be provided on the insulating fences 68a to protect the insulating fences 68a.

In an embodiment while the insulating patterns 62′ is removed in the memory cell region MA, the first upper protective layers 74a may be removed, and the second upper protective layers 74b may remain.

Referring to FIGS. 1, 2, and 3H, after removing the insulating patterns 62′ in the memory cell region MA, a conformal liner 82 may be formed on the substrate 3. In an embodiment, the liner 82 may be formed of silicon nitride.

Referring to FIGS. 1, 2, and 3I, an etching process for exposing the pad layers 22 below the contact holes 80 may be performed. For example, the pad layers 22 may be exposed by etching the liner 82 and the insulating liner 59 below the contact holes 80. Therefore, contact holes 80a exposing the pad layers 22 may be formed.

Referring to FIGS. 1, 2, and 3J, contact plugs 84 may be formed in the contact holes 80a in block S80. In an embodiment, the forming of the contact plugs 84 may include forming at least one conductive material layer filling at least the contact holes 80a, and planarizing the at least one conductive material layer to form at least one conductive material layer remaining in the contact holes 80a. For example, the forming of the contact plugs 84 may include forming at least one conductive material layer filling the contact holes 80a and covering the first protective patterns 78a remaining on the insulating fences 68a and the second protective patterns 74b and 78b on the interconnection structures BS, and planarizing the at least one conductive material layer to form at least one conductive material layer remaining in the contact holes 80a.

In an embodiment, the planarizing of the at least one conductive material layer may include performing a chemical mechanical polishing process, until the remaining first protective patterns 78a and the second protective patterns 74b and 78b are removed, and the interconnection structures BS and the insulating fences 68a are exposed. The interconnection capping layers 47 of the interconnection structures BS may be exposed. Therefore, the remaining first protective patterns 78a and the second protective patterns 74b and 78b may be removed while forming the contact plugs 84.

In an embodiment, the forming of the contact plugs 84 may include forming a first conductive material layer 84a partially filling the contact holes 80a, forming a second conductive material layer 84b on the first conductive material layer 84a, and forming a third conductive material layer 84c filling remaining portions of the contact holes 80a on the second conductive material layer 84b. The planarizing of the at least one conductive material layer may be a process of planarizing the third conductive material layer 84c. Therefore, each of the contact plugs 84 may include the first conductive material layer 84a, the second conductive material layer 84b, and the third conductive material layer 84c, sequentially stacked.

In each of the contact plugs 84, the first conductive material layer 84a may be in direct contact with and electrically connected to the pad layer 22, and may be formed as a doped silicon layer, for example, a polysilicon layer having N-type conductivity. In and embodiment, in each of the contact plugs 84, the second conductive material layer 84b may be formed as a metal-semiconductor compound layer. For example, in an embodiment the second conductive material layer 84b may include at least one of WSi, TiSi, TaSi, NiSi, or CoSi. In each of the contact plugs 84, the third conductive material layer 84c may include a plug pattern, and a conductive barrier layer covering side and bottom surfaces of the plug pattern. The conductive barrier layer may include at least one of TiN, TaN, WN, TiSiN, TaSiN, or RuTiN, and the plug pattern may include a metal such as W or the like.

In an embodiment, the plug portion 45p of the conductive line 45 may be electrically connected to a first region, for example, the first impurity region 9a, and the contact plugs 84 may be electrically connected to second regions, for example, the second impurity regions 9b through the pad layers 22.

Referring to FIGS. 1, 2, and 3K, conductive pads 87 directly contacting the contact plugs 84, respectively, and a separation insulating layer 90 separating the conductive pads 87 to be spaced apart from each other may be formed. The forming of the conductive pads 87 and the separation insulating layer 90 may include forming a pad material layer, patterning the pad material layer to form the conductive pads 87, and forming the separation insulating layer 90 filling a space between the conductive pads 87. In an embodiment, the separation insulating layer 90 may include an insulating material such as silicon nitride or the like. Each of the conductive pads 87 may vertically overlap any one of adjacent interconnection structures BS.

The conductive pads 87 may include at least one conductive material layer. For example, each of the conductive pads 87 may include a barrier layer and a conductive layer on the barrier layer. In an embodiment, the barrier layer may include at least one of TiN, TaN, WN, TiSiN, TaSiN, or RuTiN, and the conductive layer may include a metal such as W or the like. However, embodiments of the present inventive concept are not necessarily limited thereto.

In an embodiment, the above-described first protective patterns 78a may protect the insulating fences 68a from an etching process of etching the insulating patterns 62′ in FIG. 3F to form the contact holes 80a. Therefore, it is possible to prevent the insulating fences 68a from being etched by the etching process of etching the insulating patterns (62′ in FIG. 3F), thereby preventing the insulating fences 68a from being deformed. Accordingly, since the first protective patterns 78a can prevent the contact holes 80a from being deformed, the contact plugs 84 filling the contact holes 80a can be prevented from being deformed. Therefore, the first protective patterns 78a may prevent defects from occurring due to deformation of the contact plugs 84. The first protective patterns 78a may be formed on the insulating fences 68a, to stably and reliably form the contact plugs 84. In addition, the conductive pads 87 contacting the contact plugs 84 may be formed more stably and reliably.

As described above, a method of fabricating a semiconductor device according to an embodiment of the present inventive concept, described with reference to FIGS. 1, 2, and 3A to 3K, may be provided. In addition, a semiconductor device 1 manufactured by a method of fabricating a semiconductor device according to an embodiment of the present inventive concept, described with reference to FIGS. 1, 2, and 3A to 3K, may be provided. Such a semiconductor device 1 may have a shape as illustrated in the plan view of FIG. 2 and a shape as illustrated in the cross-sectional view of FIG. 3K. For example, the semiconductor device 1 as illustrated in FIGS. 2 and 3K may include the lower structure LS, the interconnection structures BS on the lower structure LS, the insulating fences 68a disposed between the interconnection structures BS in the memory cell region MA, the dummy barriers 69 disposed in the peripheral region PA and formed of the same material as the insulating fences 68a, the contact plugs 84 disposed between the interconnection structures BS and between the insulating fences 68a in the memory cell region MA, the conductive pads 87 respectively disposed on the contact plugs 84, and the separation insulating layer 90 separating the conductive pads 87, as described above.

The conductive pads 87 may vertically overlap the contact plugs 84, and extend in a horizontal direction to vertically overlap the interconnection structures BS and the insulating fences 68a. For example, each of the conductive pads 87 may overlap one of the adjacent interconnection structures BS in a vertical direction (Z).

The insulating liner 59 described with reference to FIG. 3A may remain between lateral side surfaces of the interconnection structures BS and lateral side surfaces of the contact plugs 84.

The contact plugs 84 may be electrically connected to the second impurity regions 9b of the source/drain regions SD through the pad layers 22.

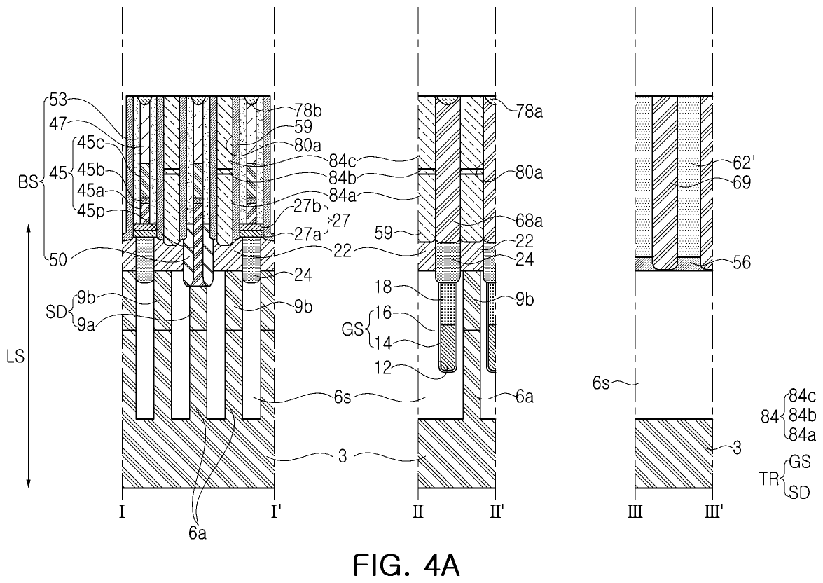

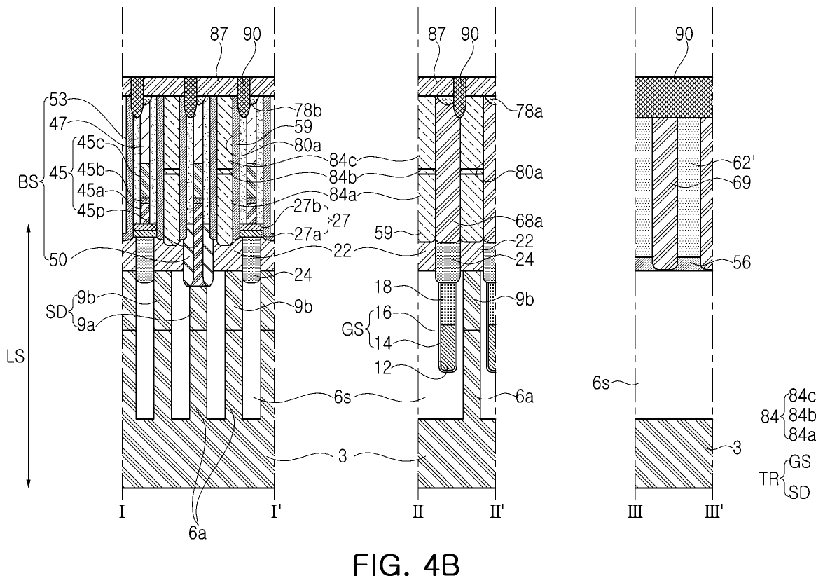

Next, referring to FIGS. 4A and 4B together with FIG. 2, a modified example of a method of fabricating a semiconductor device according to an embodiment of the present inventive concept will be described. FIGS. 4A and 4B may be cross-sectional views schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 4A, after performing the operations including the forming the contact holes 80a described in FIG. 3I, contact plugs 84 having an upper surface located on the same level as at least a portion of the first and second core protective layers 78a and 78b and filling the contact holes 80a may be formed. Therefore, while the first and second core protective layers 78a and 78b in FIG. 3I remain, the contact plugs 84 may be formed. For example, the forming of the contact plugs 84 may include forming at least one conductive material layer, and planarizing the at least one conductive material layer until the first and second core protective layers 78a and 78b are exposed, to form at least one conductive material layer remaining in the contact holes 80a.

Each of the contact plugs 84 may include a first conductive material layer 84a, a second conductive material layer 84b, and a third conductive material layer 84c, sequentially stacked, as described in FIG. 3J.

After forming the contact plugs 84, the first core protective layers 78a may remain on the insulating fences 68a, and the second core protective layers 78b may remain on the interconnection structures BS.

The first core protective layers 78a remaining on the insulating fences 68a may be referred to as first protective patterns, and the second core protective layers 78b remaining on the interconnection structures BS may be referred to as second protective patterns.

Referring to FIGS. 2 and 4B, conductive pads 87 respectively directly contacting the contact plugs 84, and a separation insulating layer 90 separating the conductive pads 87 to be spaced apart from each other, may be formed, as described in FIG. 3K. The conductive pads 87 in FIG. 4B may be in direct contact with first and second protective patterns 78a and 78b. The first and second protective patterns 78a and 78b may be formed of an insulating material such as a metal oxide, silicon nitride, or the like.

As described above, a modified example of a method of fabricating a semiconductor device according to an embodiment of the present inventive concept, described with reference to FIGS. 4A and 4B, may be provided. In addition, a semiconductor device 1 manufactured by a modified example of a method of fabricating a semiconductor device according to an embodiment of the present inventive concept, described with reference to FIGS. 4A and 4B, may be provided. Such a semiconductor device 1 may have a shape as illustrated in the plan view of FIG. 2 and a shape as illustrated in the cross-sectional view of FIG. 4B. For example, the semiconductor device 1 as illustrated in FIGS. 2 and 4B may include the lower structure LS, the interconnection structures BS on the lower structure LS, the insulating fences 68a disposed between the interconnection structures BS in the memory cell region MA, the dummy barriers 69 disposed in the peripheral region PA and formed of the same material as the insulating fences 68a, the contact plugs 84 disposed between the interconnection structures BS and between the insulating fences 68a in the memory cell region MA, the first protective patterns 78a remaining on the insulating fences 68a, the second protective patterns 78b remaining on the interconnection structures BS, the conductive pads 87 respectively disposed on the contact plugs 84, and the separation insulating layer 90 separating the conductive pads 87, as described above.

Each of the conductive pads 87 may vertically overlap any one of adjacent interconnection structures BS. The conductive pads 87 may vertically overlap the first and second protective patterns 78a and 78b. The conductive pads 87 may vertically overlap the contact plugs 84, and may extend in a horizontal direction to vertically overlap the first protective patterns 78a on the insulating fences 68a and the second protective patterns 78b on the interconnection structures BS. For example, one of the conductive pads 87 may vertically overlap at least a portion of adjacent first and second protective patterns 78a and 78b.

In each of the contact plugs 84, a portion of the contact plug 84 may be disposed on the same level as the first protective patterns 78a and the second protective patterns 78b.

Upper surfaces of the contact plugs 84 may be coplanar with upper surfaces of the first and second protective patterns 78a and 78b.

In an embodiment, each of the first protective patterns 78a and the second protective patterns 78b may be a single insulating material layer.

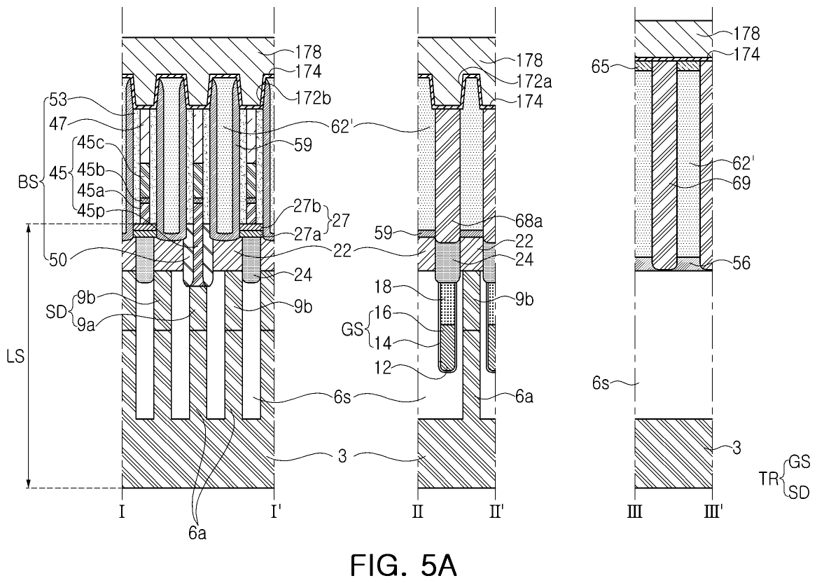

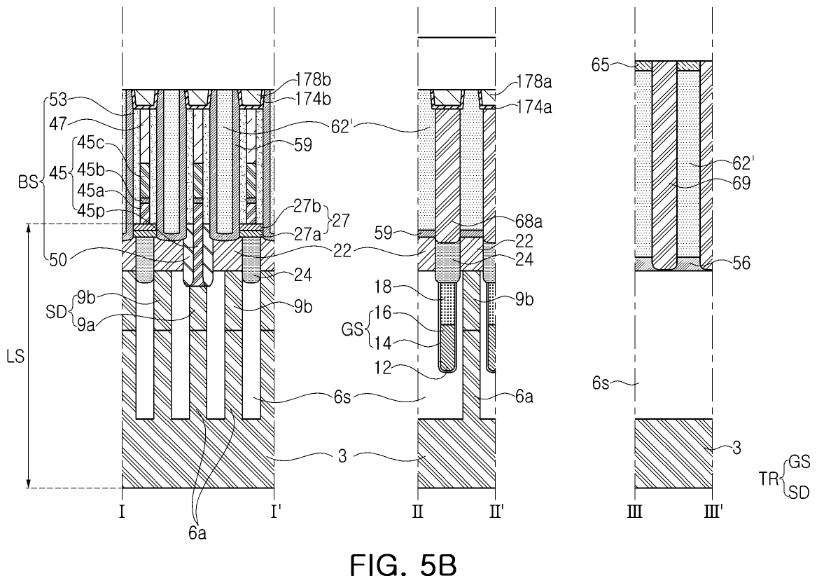

Next, referring to FIGS. 5A and 5B together with FIG. 2, a modified example of a method of fabricating a semiconductor device according to an embodiment of the present inventive concept will be described. FIGS. 5A and 5B may be cross-sectional views schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 5A, insulating fences 68 and interconnection structures BS may be partially etched, to form first recess regions 172a on the insulating fences 68 and second recess regions 172b on the interconnection structures BS, in a similar manner to that described in FIG. 3C.

A lower protective layer 174 conformally formed along inner walls of the first and second recess regions 172a and 172b, and an upper protective layer 178 filling at least the first and second recess regions 172a and 172b on the lower protective layer 174, may be formed.

In an embodiment, the lower protective layer 174 may be formed of an insulating material. For example, the lower protective layer 174 may be formed of silicon oxide. For example, the lower protective layer 174 may be formed of silicon oxide by an atomic layer deposition process. However, embodiments of the present inventive concept are not necessarily limited thereto and the lower protective layer 174 may be formed of an insulating material or a conductive material, different from silicon oxide. For example, the lower protective layer 174 may be formed of an insulating material such as silicon nitride, a metal oxide, or the like, or a conductive material such as a metal nitride or the like.

In an embodiment, the upper protective layer 178 may be formed of a conductive material. For example, the upper protective layer 178 may be formed of a metal nitride such as TiN or the like. However, embodiments of the present inventive concept are not necessarily limited thereto and a material of the upper protective layer 178 may be replaced with other materials having high etching selectivity with respect to a material of the insulating patterns 62′. For example, the upper protective layer 178 may be formed of an insulating material such as a metal oxide, silicon nitride, or the like.

Referring to FIGS. 2 and 5B, the upper protective layer 178 and the lower protective layer 174 may be etched, to form first protective patterns 174a and 178a filling the first recess regions 172a, and second protective patterns 174b and 178b filling the second recess regions 172b.

Each of the first protective patterns 174a and 178a may include a first lower protective layer 174a in which the lower protective layer 174 is formed and remains, and a first upper protective layer 178a in which the upper protective layer 178 is formed and remains. The first lower protective layer 174a may cover lateral sides and bottom surfaces of the first upper protective layer 178a.

Each of the second protective patterns 174b and 178b may include a second lower protective layer 174b in which the lower protective layer 174 is formed and remains, and a second upper protective layer 178b in which the upper protective layer 178 is formed and remains. The second lower protective layer 174b may cover lateral sides and bottom surfaces of the second upper protective layer 178b.

The first protective patterns 174a and 178a may correspond to the first protective patterns 74a and 78a described in FIG. 3F, respectively, and have the same function as the first protective patterns (74a and 78a of FIG. 3F). The second protective patterns 174b and 178b may correspond to the second protective patterns 74b and 78b described in FIG. 3F, respectively, and have the same function as the second protective patterns (74b and 78b of FIG. 3F).

Then, the method described in FIGS. 3F to 3K may be performed, to form a cross-sectional structure of the semiconductor device as illustrated in FIG. 3K.

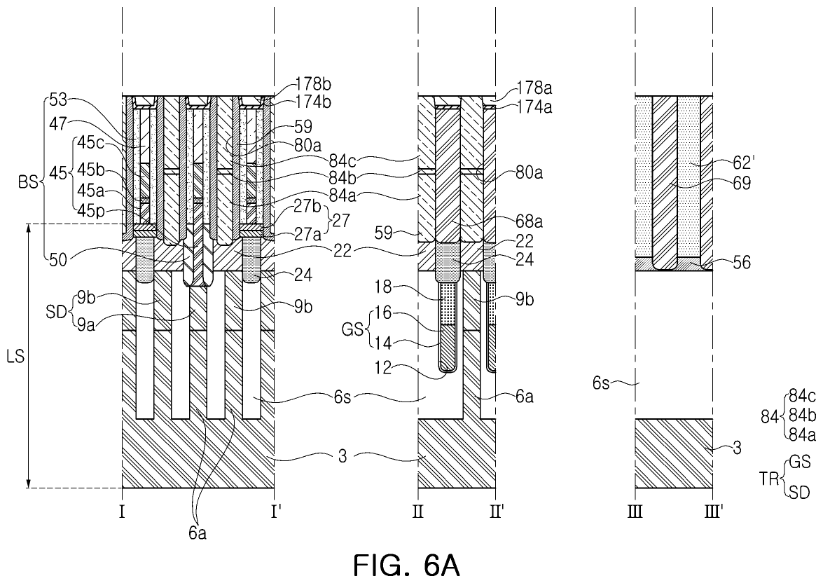

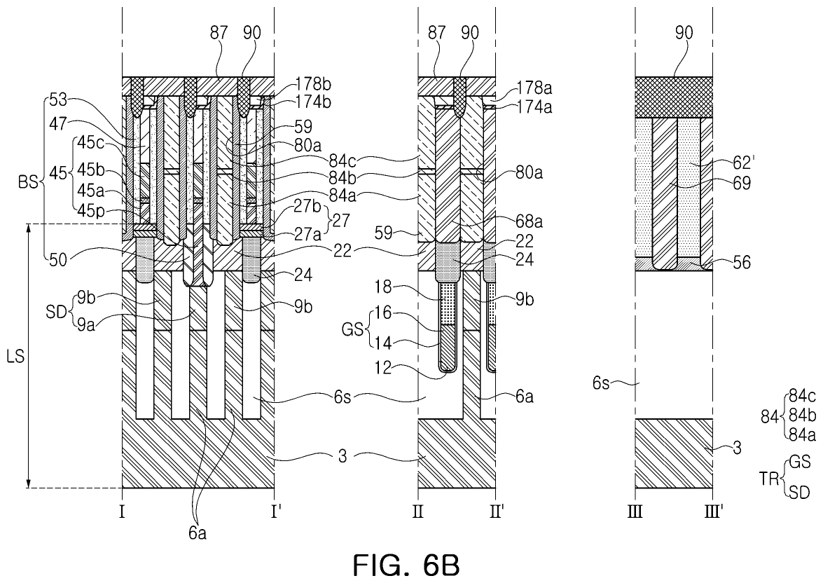

Next, referring to FIGS. 6A and 6B together with FIG. 2, a modified example of a method of fabricating a semiconductor device according to an embodiment of the present inventive concept will be described. FIGS. 6A and 6B may be cross-sectional views schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 6A, after performing the operations including the forming of the first protective patterns 174a and 178a and the second protective patterns 174b and 178b, described in FIG. 5B, and forming the contact holes 80a described in FIG. 3I, contact plugs 84 having an upper surface located on the same level as at least a portion of the first protective patterns 174a and 178a and at least a portion of the second protective patterns 174b and 178b and filling the contact holes 80a may be formed.

After performing the operations including the forming of the first protective patterns 174a and 178a and the second protective patterns 174b and 178b, described in FIG. 5B, in the forming the contact holes 80a described in FIG. 3I, a portion of the first lower protective layer 174a covering a lateral side surface of the first upper protective layer 178a, among portions of the first lower protective layer 174a covering side and bottom surfaces of the first upper protective layer 178a, may be etched and removed. Therefore, a portion of the first lower protective layer 174a covering a lower surface of the first upper protective layer 178a may remain.

In an embodiment, the first protective patterns 174a and 178a and the second protective patterns 174b and 178b may be formed of insulating materials such as a metal oxide, silicon nitride, or the like.

Each of the contact plugs 84 may include a first conductive material layer 84a, a second conductive material layer 84b, and a third conductive material layer 84c, sequentially stacked, as described in FIG. 3J.

After forming the contact plugs 84, the first protective patterns 174a and 178a may remain on the insulating fences 68a, and the second protective patterns 174b and 178b may remain on the interconnection structures BS.

Referring to FIGS. 2 and 6B, conductive pads 87 respectively contacting the contact plugs 84, and a separation insulating layer 90 separating the conductive pads 87 to be spaced apart from each other, may be formed, as described in FIG. 3K. The conductive pads 87 in FIG. 6B may be in direct contact with the first protective patterns 174a and 178a and the second protective patterns 174b and 178b.

As described above, a modified example of a method of fabricating a semiconductor device according to an embodiment of the present inventive concept, described with reference to FIGS. 6A and 6B, may be provided. In addition, a semiconductor device 1 manufactured by a modified example of a method of fabricating a semiconductor device according to an embodiment of the present inventive concept, described with reference to FIGS. 6A and 6B, may be provided. Such a semiconductor device 1 may have a shape as illustrated in the plan view of FIG. 2 and a shape as illustrated in the cross-sectional view of FIG. 6B. For example, the semiconductor device 1 as illustrated in FIGS. 2 and 6B may include the lower structure LS, the interconnection structures BS on the lower structure LS, the insulating fences 68a disposed between the interconnection structures BS in the memory cell region MA, the dummy barriers 69 disposed in the peripheral region PA and formed of the same material as the insulating fences 68a, the contact plugs 84 disposed between the interconnection structures BS and between the insulating fences 68a in the memory cell region MA, the first protective patterns 174a and 178a remaining on the insulating fences 68a, the second protective patterns 174b and 178b remaining on the interconnection structures BS, the conductive pads 87 respectively disposed on the contact plugs 84, and the separation insulating layer 90 separating the conductive pads 87, as described above.

Each of the first protective patterns 174a and 178a and the second protective patterns 174b and 178b may include at least two material layers.

Each of the conductive pads 87 may vertically overlap any one of adjacent interconnection structures BS. The conductive pads 87 may vertically overlap the first protective patterns 174a and 178a and the second protective patterns 174b and 178b. The conductive pads 87 may vertically overlap the contact plugs 84, and may extend in a horizontal direction to vertically overlap the first protective patterns 174a and 178a on the insulating fences 68a and the second protective patterns 174b and 178b on the interconnection structures BS.

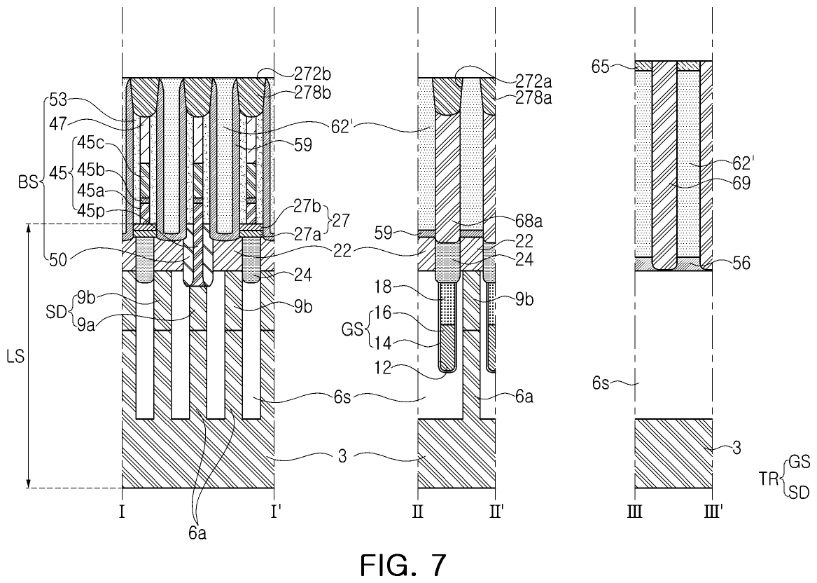

Next, referring to FIG. 7 together with FIG. 2, a modified example of a method of fabricating a semiconductor device according to an embodiment of the present inventive concept will be described. FIG. 7 may be a cross-sectional view schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 7, insulating fences 68 and interconnection structures BS may be partially etched, to form first recess regions 272a on the insulating fences 68 and second recess regions 272b on the interconnection structures BS, in a similar manner to that described in FIG. 3C.

First protective patterns 278a filling the first recess regions 272a and second protective patterns 278b filling the second recess regions 272b may be formed.

Each of the first and second protective patterns 278a and 278b may be formed as a single layer.

In an embodiment, the first and second protective patterns 278a and 278b may be formed of a conductive material. For example, the first and second protective patterns 278a and 278b may be formed of a metal nitride such as TiN or the like. However, embodiments of the present inventive concept are not necessarily limited thereto and the materials of the first and second protective patterns 278a and 278b may be replaced with other materials having high etching selectivity with respect to a material of the insulating patterns 62′. For example, the first and second protective patterns 278a and 278b may be formed of an insulating material such as a metal oxide, silicon nitride, or the like.

The first protective patterns 278a may correspond to the first protective patterns 74a and 78a described in FIG. 3F, and have the same function as the first protective patterns (74a and 78a of FIG. 3F). The second protective patterns 278b may correspond to the second protective patterns 74b and 78b described in FIG. 3F, and have the same function as the second protective patterns (74b and 78b of FIG. 3F).

Then, the method described in FIGS. 3F to 3K may be performed, to form a cross-sectional structure of the semiconductor device as illustrated in FIG. 3K.

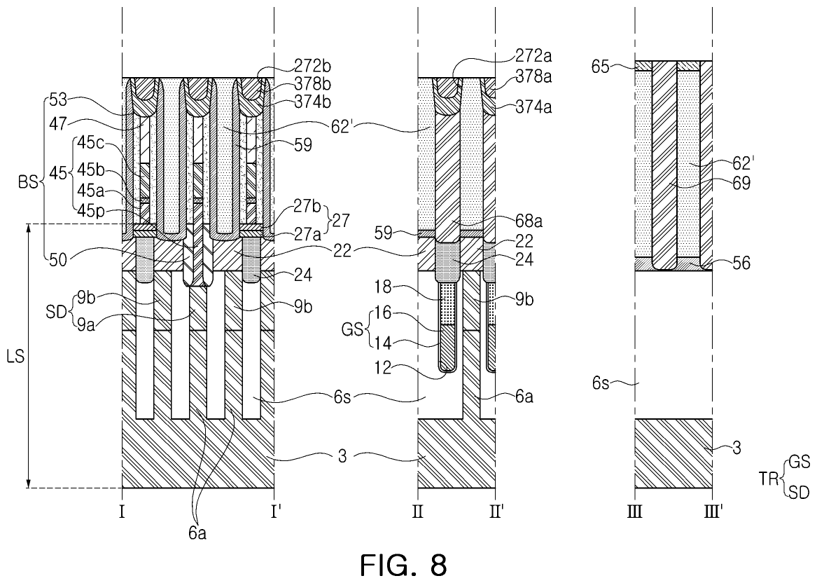

Next, referring to FIG. 8 together with FIG. 2, a method of fabricating a semiconductor device according to an embodiment of the present inventive concept will be described. FIG. 8 may be a cross-sectional view schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 8, insulating fences 68 and interconnection structures BS may be partially etched, to form first recess regions 272a on the insulating fences 68 and second recess regions 272b on the interconnection structures BS, in a similar manner to that described in FIG. 7.

First protective patterns 374a and 378a filling the first recess regions 272a and second protective patterns 374b and 378b filling the second recess regions 272b may be formed.

Each of the first protective patterns 374a and 378a may include a first lower protective layer 374a and a first upper protective layer 378a on the first lower protective layer 374a. The first lower protective layer 374a may cover lateral side and bottom surfaces of the first upper protective layer 378a. In the first lower protective layer 374a, a portion covering the bottom surface of the first upper protective layer 378a may be thicker than a portion covering the side surface of the first upper protective layer 378a.

Each of the second protective patterns 374b and 378b may include a second lower protective layer 374b and a second upper protective layer 378b on the second lower protective layer 374b. The second lower protective layer 374b may cover lateral side and bottom surfaces of the second upper protective layer 378b. In the second lower protective layer 374b, a portion covering the bottom surface of the second upper protective layer 378b may be thicker than a portion covering the side surface of the second upper protective layer 378b.

In an embodiment, the first and second lower protective layers 374a and 374b may be formed of an insulating material. For example, the first and second lower protective layers 374a and 374b may be formed of silicon oxide. However, embodiments of the present inventive concept are not necessarily limited thereto. For example, in an embodiment, the first and second lower protective layers 374a and 374b may be formed of an insulating material or a conductive material, different from silicon oxide. For example, the first and second lower protective layers 374a and 374b may be formed of an insulating material such as silicon nitride, a metal oxide, or the like, or a conductive material such as a metal nitride or the like.

In an embodiment, the first and second upper protective layers 378a and 378b may be formed of a conductive material. For example, the first and second upper protective layers 378a and 378b may be formed of a metal nitride such as TiN or the like. However, embodiments of the present inventive concept are not necessarily limited thereto and the materials of the first and second upper protective layers 378a and 378b may be replaced with other materials having high etching selectivity with respect to a material of the insulating patterns 62′. For example, the first and second upper protective layers 378a and 378b may be formed of an insulating material such as a metal oxide, silicon nitride, or the like.

The first protective patterns 374a and 378a may correspond to the first protective patterns 74a and 78a described in FIG. 3F, and have the same function as the first protective patterns (74a and 78a of FIG. 3F). The second protective patterns 374b and 378b may correspond to the second protective patterns 74b and 78b described in FIG. 3F, and have the same function as the second protective patterns (74b and 78b of FIG. 3F).

Then, the method described in FIGS. 3F to 3K may be performed, to form a cross-sectional structure of the semiconductor device as illustrated in FIG. 3K.

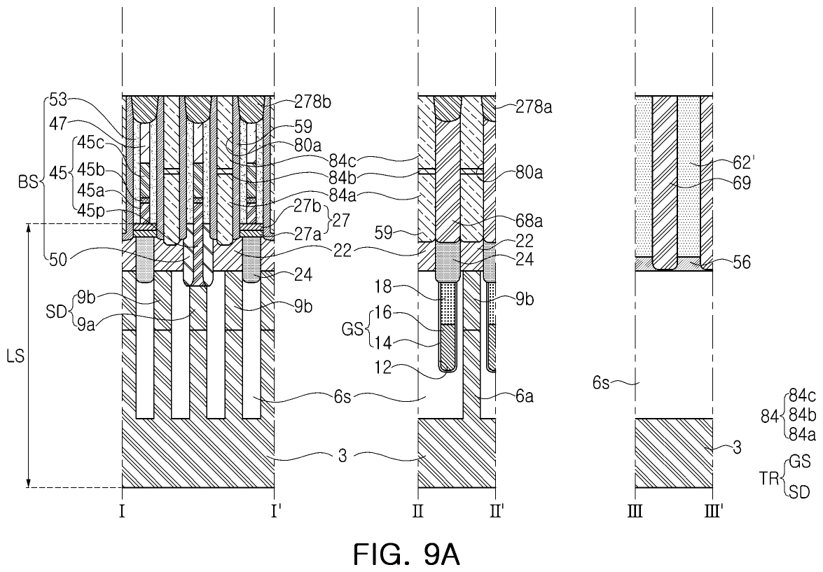

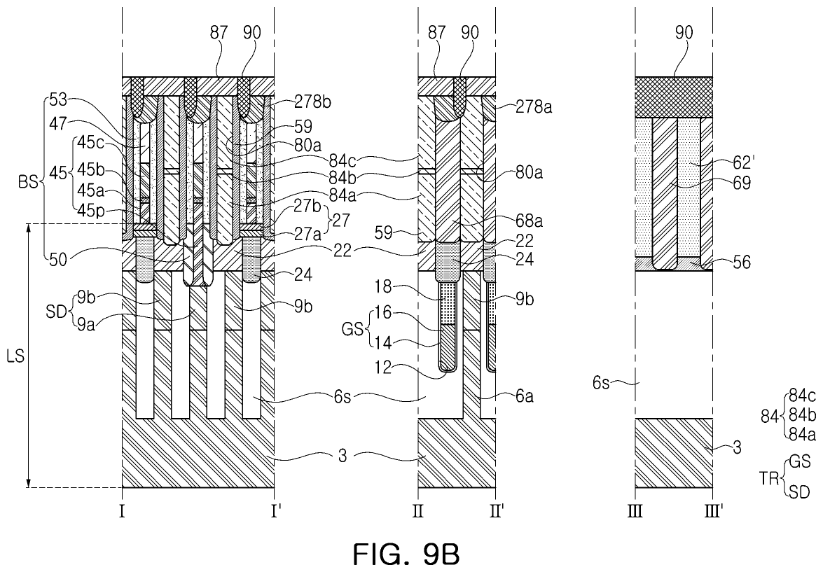

Next, referring to FIGS. 9A and 9B together with FIG. 2, a modified example of a method of fabricating a semiconductor device according to an embodiment of the present inventive concept will be described. FIGS. 9A and 9B may be cross-sectional views schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 9A, after performing the operations including the forming the first protective patterns 278a and the second protective patterns 278b, described in FIG. 7, and forming the contact holes 80a described in FIG. 3I, contact plugs 84 may be formed having an upper surface located on the same level as at least a portion of the first protective patterns 278a and at least a portion of second protective patterns 278b and filling the contact holes 80a.

In an embodiment, the first protective patterns 278a and the second protective patterns 278b may be formed of insulating materials such as a metal oxide, silicon nitride, or the like.

Each of the contact plugs 84 may include a first conductive material layer 84a, a second conductive material layer 84b, and a third conductive material layer 84c, sequentially stacked, as described in FIG. 3J.

After forming the contact plugs 84, the first protective patterns 278a may remain on the insulating fences 68a, and the second protective patterns 278b may remain on the interconnection structures BS.

Referring to FIGS. 2 and 9B, conductive pads 87 respectively directly contacting the contact plugs 84, and a separation insulating layer 90 separating the conductive pads 87 to be spaced apart from each other, may be formed, as described in FIG. 3K. The conductive pads 87 in FIG. 9B may be in direct contact with the first protective patterns 278a and the second protective patterns 278b.

As described above, a modified example of a method of fabricating a semiconductor device according to an embodiment of the present inventive concept, described with reference to FIGS. 9A and 9B, may be provided. In addition, a semiconductor device 1 manufactured by a modified example of a method of fabricating a semiconductor device according to an embodiment of the present inventive concept, described with reference to FIGS. 9A and 9B, may be provided. Such a semiconductor device 1 may have a shape as illustrated in the plan view of FIG. 2 and a shape as illustrated in the cross-sectional view of FIG. 9B. For example, the semiconductor device 1 as illustrated in FIGS. 2 and 9B may include the lower structure LS the interconnection structures BS on the lower structure LS, the insulating fences 68a disposed between the interconnection structures BS in the memory cell region MA, the dummy barriers 69 disposed in the peripheral region PA and formed of the same material as the insulating fences 68a, the contact plugs 84 disposed between the interconnection structures BS and between the insulating fences 68a in the memory cell region MA, the first protective patterns 278a remaining on the insulating fences 68a, the second protective patterns 278b remaining on the interconnection structures BS, the conductive pads 87 respectively disposed on the contact plugs 84, and the separation insulating layer 90 separating the conductive pads 87, as described above. The separation insulating layer may directly contact the first and second protective patterns 278a, 278b.

Each of the conductive pads 87 may vertically overlap any one of adjacent interconnection structures BS. The conductive pads 87 may vertically overlap the first protective patterns 278a and the second protective patterns 278b. The conductive pads 87 may vertically overlap the contact plugs 84, and may extend in a horizontal direction to vertically overlap the first protective patterns 278a on the insulating fences 68a and the second protective patterns 278b on the interconnection structures BS.

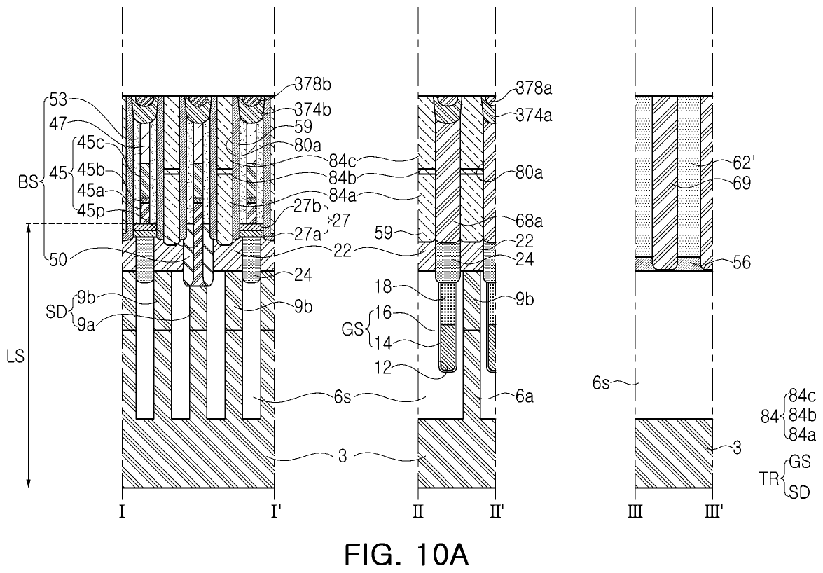

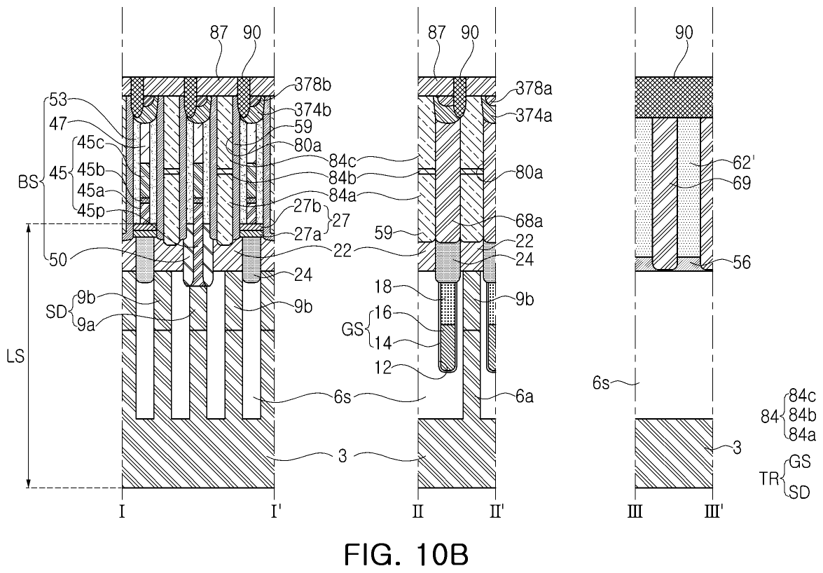

Next, referring to FIGS. 10A and 10B together with FIG. 2, a modified example of a method of fabricating a semiconductor device according to an embodiment of the present inventive concept will be described. FIGS. 10A and 10B may be cross-sectional views schematically illustrating a modified example of a method of fabricating a semiconductor device according to an embodiment of the present inventive concept, and may illustrate regions taken along line I-I′, line II-II′, and line III-III′ of FIG. 2.

Referring to FIGS. 2 and 10A, after performing the operations including the forming the first protective patterns 374a and 378a and the second protective patterns 374b and 378b, described in FIG. 8, and forming the contact holes 80a described in FIG. 3I, contact plugs 84 having an upper surface located on the same level as at least a portion of the first protective patterns 374a and 378a and at least a portion of the second protective patterns 374b and 378b and filling the contact holes 80a may be formed.

In an embodiment, the first protective patterns 374a and 378a and the second protective patterns 374b and 378b may be formed of insulating materials such as a metal oxide, silicon nitride, or the like.

Each of the contact plugs 84 may include a first conductive material layer 84a, a second conductive material layer 84b, and a third conductive material layer 84c, sequentially stacked, as described in FIG. 3J.

After forming the contact plugs 84, the first protective patterns 374a and 378a may remain on the insulating fences 68a, and the second protective patterns 374b and 378b may remain on the interconnection structures BS.

Referring to FIGS. 2 and 10B, conductive pads 87 respectively directly contacting the contact plugs 84, and a separation insulating layer 90 separating the conductive pads 87 to be spaced apart from each other, may be formed, as described in FIG. 3K. The conductive pads 87 in FIG. 9B may be in direct contact with the first protective patterns 374a and 378a and the second protective patterns 374b and 378b.

As described above, a modified example of a method of fabricating a semiconductor device according to an embodiment of the present inventive concept, described with reference to FIGS. 10A and 10B, may be provided. In addition, a semiconductor device 1 manufactured by a modified example of a method of fabricating a semiconductor device according to an embodiment of the present inventive concept, described with reference to FIGS. 10A and 10B, may be provided. Such a semiconductor device 1 may have a shape as illustrated in the plan view of FIG. 2 and a shape as illustrated in the cross-sectional view of FIG. 10B. For example, the semiconductor device 1 as illustrated in FIGS. 2 and 10B may include the lower structure LS, the interconnection structures BS on the lower structure LS, the insulating fences 68a disposed between the interconnection structures BS in the memory cell region MA, the dummy barriers 69 disposed in the peripheral region PA and formed of the same material as the insulating fences 68a, the contact plugs 84 disposed between the interconnection structures BS and between the insulating fences 68a in the memory cell region MA, the first protective patterns 374a and 378a remaining on the insulating fences 68a, the second protective patters 374b and 378b remaining on the interconnection structures BS, the conductive pads 87 respectively disposed on the contact plugs 84, and the separation insulating layer 90 separating the conductive pads 87, as described above.

Each of the conductive pads 87 may vertically overlap any one of adjacent interconnection structures BS. The conductive pads 87 may vertically overlap the first protective patterns 374a and 378a and the second protective patterns 374b and 378b. The conductive pads 87 may vertically overlap the contact plugs 84, and may extend in a horizontal direction to vertically overlap the first protective patterns 374a and 378a on the insulating fences 68a and the second protective patterns 374b and 378b on the interconnection structures BS.

The first protective patterns 374a and 378a may include a first lower protective layer 374a and a first upper protective layer 378a on the first lower protective layer 374a, as described in FIG. 9A. The second protective patterns 374b and 378b may include a second lower protective layer 374b and a second upper protective layer 378b on the second lower protective layer 374b, as described in FIG. 9A.

The first lower protective layer 374a may cover lateral side and bottom surfaces of the first upper protective layer 378a. In the first lower protective layer 374a, a portion covering the bottom surface of the first upper protective layer 378a may be thicker than a portion covering the lateral side surface of the first upper protective layer 378a. The second lower protective layer 374b may cover lateral side and bottom surfaces of the second upper protective layer 378b. In the second lower protective layer 374b, a portion covering the bottom surface of the second upper protective layer 378b may be thicker than a portion covering the lateral side surface of the second upper protective layer 378b. The conductive pads 87 may be in direct contact with upper surfaces of the first and second lower protective layers 374a and 374b and upper surfaces of the first and second upper protective layers 378a and 378b.

According to embodiments of the present inventive concept, a method of fabricating a semiconductor device, including forming insulating patterns, forming insulating fences between the insulating patterns, forming protective patterns on the insulating fences, forming contact holes by etching the insulating patterns using the protective patterns as etching masks, and forming contact plugs in the contact holes, and the semiconductor device manufactured by the method, may be provided.

The protective patterns may protect the insulating fences from an etching process of etching the insulating patterns to form the contact holes. Therefore, it is possible to prevent the insulating fences from being etched by the etching process of etching the insulating patterns, thereby preventing the insulating fences from being deformed. Therefore, since the protective patterns may prevent the contact holes from being deformed, the contact plugs filling the contact holes may be prevented from being deformed. Therefore, the protective patterns may prevent defects from occurring due to deformation of the contact plugs. The protective patterns may be formed on the insulating fences to stably and reliably form the contact plugs.

The various advantages and effects of embodiments of the present inventive concept are not limited to the above.

While non-limiting embodiments have been illustrated and described above, it will be apparent to those skilled in the art that modifications and variations could be made without departing from the scope of the present inventive concept.

1. A method of fabricating a semiconductor device, comprising:
forming interconnection structures on a lower structure;
forming an insulating layer between the interconnection structures;
patterning the insulating layer to form insulating patterns;
forming an insulating fence between the insulating patterns;
forming a first protective pattern on the insulating fence;
etching the insulating patterns after the forming of the first protective pattern to form contact holes; and
forming contact plugs in the contact holes.

2. The method of claim 1, further comprising:
forming second protective patterns on the interconnection structures,
wherein the second protective patterns and the first protective pattern are simultaneously formed.

3. The method of claim 1, further comprising removing the first protective pattern during the forming of the contact plugs.

4. The method of claim 3, wherein the first protective pattern comprises a metal nitride.

5. The method of claim 1, wherein the forming of the contact plugs comprises:
forming at least one conductive material layer that at least fills the contact holes; and
planarizing the at least one conductive material layer until the first protective pattern is removed and the insulating fence is exposed.

6. The method of claim 1, wherein at least a portion of the first protective pattern remains after the forming of the contact plugs.

7. The method of claim 6, wherein the first protective pattern comprises an insulating material.

8. The method of claim 6, wherein the forming of the contact plugs comprises:
forming at least one conductive material layer that at least fills the contact holes; and
planarizing the at least one conductive material layer, wherein at least a portion of the first protective pattern remains after the planarizing.

9. The method of claim 1, wherein the forming of a first protective pattern on the insulating fence comprises:
forming an upper recess region by performing a first partial etching of the insulating fence;
forming a first protective layer coveting a sidewall of the upper recess region and exposing a lower surface of the upper recess region;
forming a lower recess region by performing a second partial etching of the insulating fence below the lower surface of the upper recess region exposed by the first protective layer; and
forming a second protective layer filling the lower recess region and the upper recess region,
wherein the first protective layer and the second protective layer constitute the first protective pattern.

10. The method of claim 9, further comprising:
removing the first protective layer during the forming of the contact holes by etching the insulating patterns; and
removing the second protective layer during the forming of the contact plugs in the contact holes.

11. The method of claim 10, wherein:
the first protective layer is formed of an insulating material; and
the second protective layer is formed of a conductive material.

12. The method of claim 9, further comprising:
removing the first protective layer during the forming of the contact holes by etching the insulating patterns,
wherein at least a portion of the second protective layer remains after the forming of the contact plugs in the contact holes.

13. The method of claim 1, wherein the forming of the first protective pattern on the insulating fence comprises partially etching the insulating fence to form a recess region, and filling the recess region with the first protective pattern.

14. The method of claim 13, wherein the filling of the recess region with the first protective pattern comprises:
forming a first protective layer covering an inner wall of the recess region;
forming a second protective layer on the first protective layer and filling a remaining portion of the recess region,
wherein, at least a portion of the first protective layer and at least a portion of the second protective layer remain after the forming of the contact plugs in the contact holes.

15. A method of fabricating a semiconductor device, comprising:
forming a lower structure including first regions and second regions;
forming interconnection structures on the lower structure, the interconnection structures are electrically connected to the first regions;
forming patterns between the interconnection structures;
forming an insulating fence between the patterns;
simultaneously forming a first protective pattern on the insulating fence and second protective patterns on the interconnection structures;
etching the patterns after the forming of the first and second protective patterns to form contact holes; and
forming contact plugs in the contact holes, the contact plugs are electrically connected to the second regions.

16. The method of claim 15, further comprising removing the first and second protective patterns during the forming of the contact plugs.

17. The method of claim 15, wherein, at least a portion of the first and second protective patterns remain after the forming contact plugs.

18. A method of fabricating a semiconductor device, comprising:
forming an isolation layer defining active regions on a substrate;
forming cell transistors including gate structures and first and second impurity regions, wherein the gate structures cross the active regions and extend into the isolation layer, and wherein the first and second impurity regions are formed in the active regions;
forming bit line structures disposed on the cell transistors, the active regions, and the isolation layer, the bit line structures extending parallel to each other;
forming insulating patterns between the bit line structures;
forming an insulating fence between the insulating patterns;
simultaneously forming a first protective pattern on the insulating fence and second protective patterns on the bit line structures;
etching the insulating patterns after the forming of the first and second protective patterns to form contact holes; and
forming contact plugs in the contact holes.

19. The method of claim 18, wherein:
each of the bit line structures comprises a bit line including plug portions electrically connected to the first impurity regions, respectively, an insulating capping layer disposed on the bit line, and insulating spacers disposed on a lateral side surface of the bit line and a lateral side surface of the insulating capping layer;
the second protective patterns are formed on the insulating capping layers of the bit line structures: and
the first and second protective patterns are removed during the forming of the contact plugs.

20. The method of claim 18, wherein:
each of the bit line structures comprises a bit line including plug portions electrically connected to the first impurity regions, respectively, an insulating capping layer disposed on the bit line, and insulating spacers disposed on a lateral side surface of the bit line and a lateral side surface of the insulating capping layer,
the second protective patterns are formed on the insulating capping layers of the bit line structures, and
at least a portion of the first and second protective patterns remain after the forming contact plugs.

21-25. (canceled)
